(19) United States
(12) Patent Application Publication
(10) Pub. No.: US 2010/0282289 A1
(43) Pub. Date: Nov. 11, 2010

(54) SOLAR GENERATOR CAPABLE OF POWER TRACKING AND ELECTRIC CHARACTERISTIC CURVE MEASUREMENT AND METHOD FOR REALIZING THE SAME

(76) Inventors: Tsai-Fu Wu, Chia-Yi (TW); Huai-Sheng Tsai, Chia-Yi (TW); Kung-Yen Lee, Chia-Yi (TW)

Correspondence Address: SINORICA, LLC, 2275 Research Blvd., Suite 500, ROCKVILLE, MD, 20850, US

(21) Appl. No.: 12/436,892

(22) Filed: May 7, 2009

(51) Int. Cl. H01L 31/042

(52) U.S. Cl. 136/244

(57) ABSTRACT

A solar generator capable of power tracking and electric characteristic curve measurement and a method for realizing the same is disclosed. The solar generator of the present invention comprises at least one solar panel receiving solar energy, converting the solar energy into electric energy, and outputting the electric energy; an electric tracking-measuring circuit connected with the solar panel and the external load; and a processor connected with the electric tracking-measuring circuit, controlling the electric tracking-measuring circuit to receive the electric energy and output the electric energy to the external load at the highest power. When the illumination on the solar panel is greater than a preset value, the processor controls the electric tracking-measuring circuit to measure the I-V characteristic curve of the electric energy to determine the operation status of the solar panel.

### BACKGROUND OF THE INVENTION

1. Field of the Invention

The present invention relates to a power generator technology, particularly to a solar generator capable of power tracking and electric characteristic curve measurement and a method for realizing the same.

2. Description of the Related Art

With the persistent growth of global energy demand and the awakening of environmental protection consciousness, renewable energies have assumed more and more importance in many nations, especially solar energy.

A photovoltaic cell has a nonlinear I-V relationship and has different I-V characteristic curves under different illuminations or at different temperatures, and each characteristic curve has a maximum power point. To make the most of solar energy and promote the efficiency of solar panels, a solar generator system usually has a maximum power point tracking (MPPT) function.

Refer to FIG. 1 for the architecture of a conventional solar generator system. In the conventional solar generator system, a converter 12 containing an MPPT circuit extracts the highest power from a solar panel module 10 to a DC (Direct Current) bus or an inverter 14. The DC bus supplies power to a DC load 16, and the inverter 14 transforms the DC power into AC (Alternating Current) power and supplies the AC power to an AC load 18.

Refer to FIG. 2 for the architecture of another conventional solar generator system. In the conventional solar generator system, an inverter 20 containing an MPPT circuit extracts the highest power from a solar panel module 10 and directly transfers the highest power to the commercial power system.

A solar panel module consists of several solar panels connected in series or in parallel. The solar generator system must be installed outdoors. Thus, aging of, damage to, or shade on the solar panels usually affects the output of the solar panel module. However, the conventional solar generator system has only the MPPT function but cannot learn the I-V characteristic curve thereof. Therefore, the user is less likely to immediately perceive the malfunction of or the shade on the conventional solar generator system.

Accordingly, the present invention proposes a solar generator capable of power tracking and electric characteristic curve measurement and a method for realizing the same to overcome the abovementioned problems.

### SUMMARY OF THE INVENTION

The primary objective of the present invention is to provide a solar generator capable of power tracking and electric characteristic curve measurement and a method for realizing the same, wherein an electric tracking-measuring circuit is normally used to extract the highest power from solar panels to external circuits and is periodically used to measure the I-V characteristic curve of the solar panels to check whether the solar panels are malfunctioning or shaded, whereby the efficiency and reliability of the solar generator is promoted.

To achieve the abovementioned objective, the present invention proposes a solar generator capable of power tracking and electric characteristic curve measurement, which is connected to at least one external load, and which comprises at least one solar panel, an electric tracking-measuring circuit, an illuminometer, and a processor. The solar panel receives solar energy, converts the solar energy into electric energy and outputs the electric energy. The solar panel is connected with the external load via the electric tracking-measuring circuit. The processor is connected with the illuminometer and the electric tracking-measuring circuit. The illuminometer detects the sunshine illumination on the solar panel. The processor controls the electric tracking-measuring circuit to receive electric energy and output the electric energy at the highest power. When the illumination is higher than a preset value, the processor controls the electric tracking-measuring circuit to measure the I-V characteristic curve to learn the operation status of the solar panel.

The present invention also proposes a method for realizing a solar generator capable of power tracking and electric characteristic curve measurement, which comprises steps: using at least one solar panel to receive solar energy, convert the solar energy into electric energy, and output the electric energy to an electric tracking-measuring circuit connected with at least one external load; controlling the electric tracking-measuring circuit to normally receive the electric energy and output the electric energy to the external load at the highest power and to periodically check whether the sunshine illumination is greater than a preset value; if the sunshine illumination is greater than the preset value, controlling the electric tracking-measuring circuit to receive the electric energy and measuring the I-V curve of the electric energy to determine the operation status of the solar panel; if the sunshine illumination is not greater than the preset value, controlling the electric tracking-measuring circuit to keep on supplying the electric energy to the external load.

Below, the embodiments are described in detail in cooperation with the drawings to make easily the technical contents and accomplishments of the present invention.

### BRIEF DESCRIPTION OF THE DRAWINGS

FIG. 1 is a diagram schematically showing the architecture of a conventional device converting solar energy into electric energy and outputting electric energy to DC loads and AC loads;

FIG. 2 is a diagram schematically showing the architecture of a conventional device converting solar energy into electric energy and outputting electric energy to AC loads;

FIG. 3 is a diagram schematically showing the architecture of a solar generator according to a first embodiment of the present invention;

FIG. 4 is a diagram schematically showing the architecture of a solar generator according to a second embodiment of the present invention;

FIG. 5 is a diagram showing an I-V characteristic curve of a normal solar panel;

FIG. 6 is a diagram showing an I-V characteristic curve of an abnormal solar panel; and

FIG. 7 is a diagram showing an I-V characteristic curve of another abnormal solar panel.

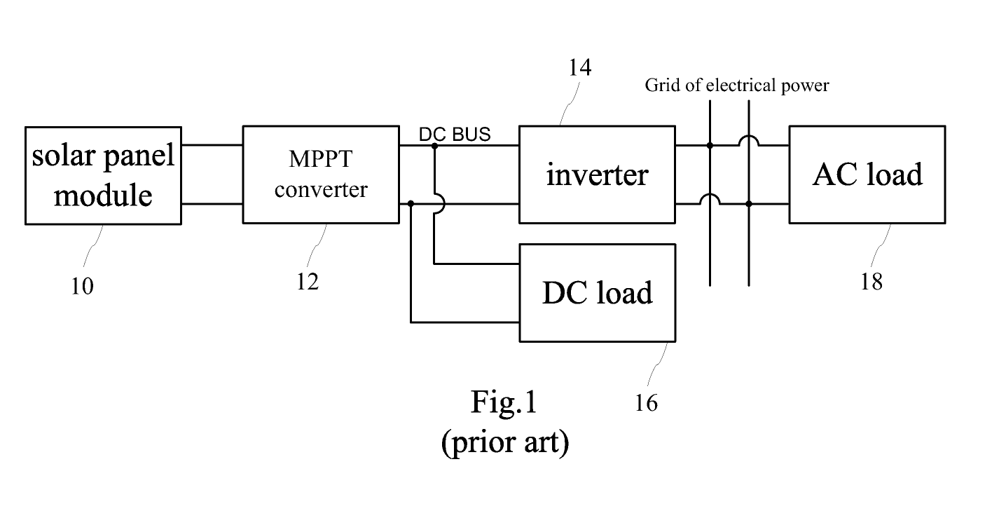

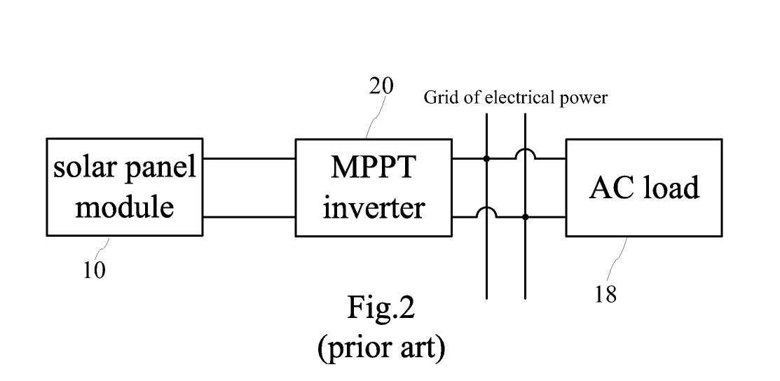

### DETAILED DESCRIPTION OF THE INVENTION

The present invention is characterized in that the solar generator uses an illuminometer, a digital signal processor and an electric tracking-measuring circuit to automatically check whether the solar panels are malfunctioning or shaded.

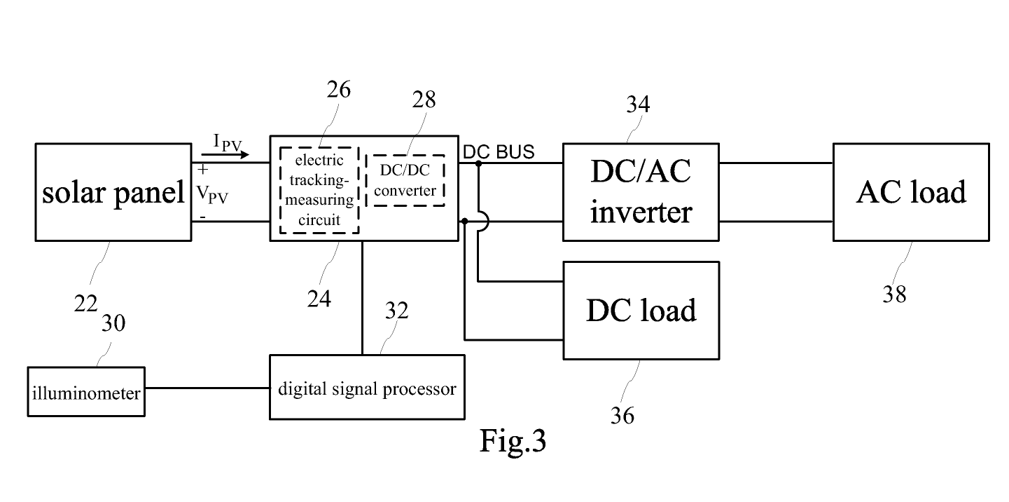

Refer to FIG. 3 for a first embodiment of the present invention. The solar generator of the present invention comprises at least one solar panel 22, an electric tracking-measuring converter 24, a digital signal processor 32 and an illuminometer 30. The solar panel 22 is connected with the converter 24, transforms the received solar energy into electric energy and outputs the electric energy. The illuminometer 30 detects the sunshine illumination on the solar panel 22. The electric tracking-measuring converter 24 integrates a DC/DC converter 28 and an electric tracking-measuring circuit 26. The electric tracking-measuring converter 24 is connected with a DC bus and a DC/AC converter 34. The DC bus and the DC/AC inverter 34 are respectively connected to a DC load 36 and an AC load 38.

The digital signal processor 32 is connected with the illuminometer 30 and the electric tracking-measuring converter 24. The digital signal processor 32 controls the electric tracking-measuring circuit 26 of the electric tracking-measuring converter 24 to receive the electric energy output by the solar panel 22, and outputs the electric energy at the highest power. The DC/DC converter 28 receives the electric energy output by the electric tracking-measuring circuit 26, converts the electric energy into a stable DC power and outputs the stable DC power to the DC load 36 or the inverter 34. The inverter 34 converters the stable DC power into a stable AC power and outputs the stable AC power to the AC load 38. During the abovementioned power-supply process, the digital signal processor 32 periodically checks whether the illumination currently detected by the illuminometer 30 is greater than a preset value. If the current illumination is greater than the preset value, the digital signal processor 32 interrupts the original power-supply process and controls the electric tracking-measuring circuit 26 to measure the I-V (current-voltage) characteristic curve of the electric energy and examine the operation status of the solar panel 22 to learn whether the solar panel 22 is malfunctioning or shaded. If the current illumination is not greater than the preset value, the digital signal processor 32 controls the electric tracking-measuring circuit 26 to keep on receiving the electric energy and outputting the electric energy to the DC load 36 or the AC load 38 at the highest power.

Before controlling the electric tracking-measuring circuit 26 to measure the I-V characteristic curve, the digital signal processor 32 should control the electric tracking-measuring circuit 26 to receive the electric energy output by the solar panel 22 in a condition of sufficient sunshine to establish reference I-V characteristic curves. Then, the reference I-V characteristic curves are stored in the digital signal processor 32. When determining that the current illumination is greater than the preset value, the digital signal processor 32 compares the I-V characteristic curve detected currently with the reference I-V characteristic curves to determine the operation status of the solar panel 22. The results are used as the reference for the maintenance of the solar generator. Thereby, the efficiency and reliability of the solar generator is promoted. If none reference I-V characteristic curve is established in the digital signal processor, reference I-V characteristic curves may be programmed in the digital signal processor 32 beforehand for comparison.

No matter when measuring a reference I-V characteristic curve or a working I-V characteristic curve, the electric tracking-measuring circuit 26 incrementally increases or decreases the voltage (Vₚᵥ) or current (Iₚᵥ) to establish the I-V characteristic curve. If the electric tracking-measuring circuit 26 is of a voltage-increasing type, the voltage in the I-V curve can extend to as high as the output voltage of the solar panel 22. If the electric tracking-measuring circuit 26 is of a voltage-decreasing type, the voltage in the I-V curve can extend to as low as the output voltage of the solar panel 22.

Below is described the operation of the present invention. When the sunshine is sufficient and the solar generator operates normally, the digital signal processor 32 controls the electric tracking-measuring circuit 26 to incrementally increase or decrease the voltage or current supplied by the solar panel 22 to establish the reference I-V characteristic curves. The reference I-V characteristic curves are recorded in the digital signal processor 32. Next, the digital signal processor 32 controls the electric tracking-measuring circuit 26 to receive the electric energy output by the solar panel 22 and output the electric energy to the load at the highest power. The digital signal processor 32 will periodically check whether the illumination detected by the illuminometer 30 currently is greater than a preset value. If the current illumination is greater than the preset value, the digital signal processor 32 interrupts the MPPT function and the original power-supply process and then controls the electric tracking-measuring circuit 26 to incrementally increase or decrease the voltage or current supplied by the solar panel 22 to measure the I-V characteristic curve of the solar panel 22. Then, the digital signal processor 32 compares the measured I-V characteristic curve with the reference I-V characteristic curve to determine whether the solar generator operates normally or whether the solar panel 22 is malfunctioning or shaded. If the current illumination is not greater than the preset value, the digital signal processor 32 controls the electric tracking-measuring circuit 26 to keep on receiving electric energy and outputting the electric energy to the load at the highest power.

In the abovementioned operation, if none reference I-V characteristic curve is established in the digital signal processor 32, reference I-V characteristic curves may be programmed in the digital signal processor 32 beforehand for comparison.

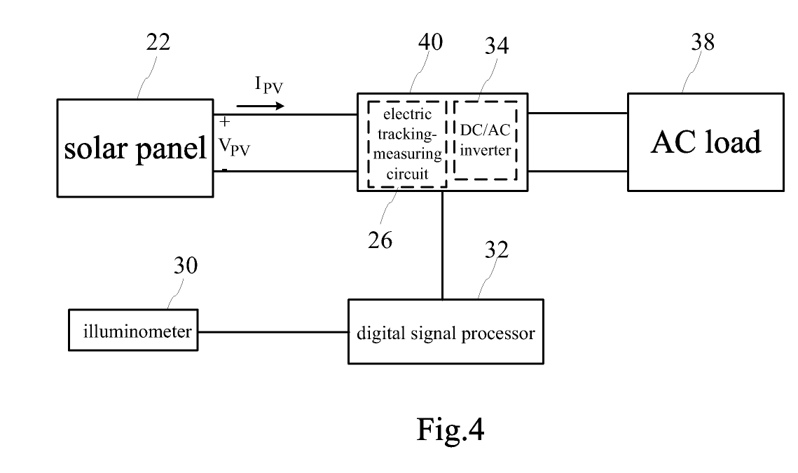

Refer to FIG. 4 for a second embodiment of the present invention. The second embodiment is different from the first embodiment in that the electric tracking-measuring circuit 26 and the DC/AC inverter 34 are integrated to form an electric tracking-measuring inverter 40. In FIG. 4, the DC/DC converter and the DC load are omitted, and the electric tracking-measuring inverter 40 is directly connected with the solar panel 22, the AC load 38 and the digital signal processor 32. During the process of supplying power to the load, the electric tracking-measuring circuit 26 of the electric tracking-measuring inverter 40 receives the electric energy output by the solar panel 22 and outputs the electric energy at the highest power. Then, the DC/AC inverter 34 receives the electric energy, converts the electric energy into a stable AC power and outputs the stable AC power to the AC load 38.

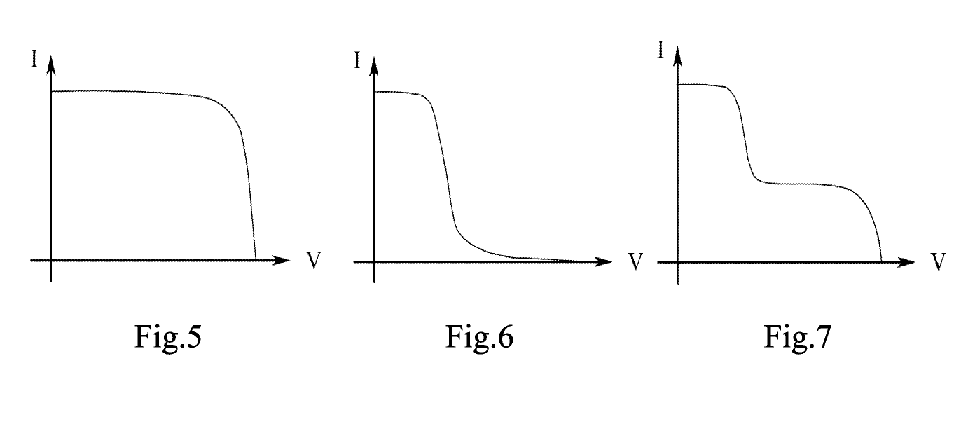

Refer to FIGS. 5-7. FIG. 5 shows a normal I-V characteristic curve of a solar panel, wherein the middle portion is a smooth segment. When the solar panel is malfunctioning or shaded, the I-V characteristic curve becomes that shown in FIG. 6 or FIG. 7. The curve shown in FIG. 6 or FIG. 7 is distorted in the middle portion, which is distinct from the normal condition. Therefore, having the information of the middle portion is sufficient to determine whether the solar panel is normal although the output voltage of the solar panel makes the electric tracking-measuring circuit unlikely to obtain a complete I-V characteristic curve.

In conclusion, the present invention outperforms the conventional technology in that the present invention can automatically check whether the solar panel is malfunctioning or shaded. Thereby, the present invention can promote the efficiency and reliability of the solar generator. Therefore, the present invention is a very useful innovation.

The embodiments described above are only to exemplify the present invention but not to limit the scope of the present invention. Therefore, any equivalent modification or variation according to the shape, structure, characteristic or spirit disclosed in the present invention is to be also included within the scope of the present invention, which is based on the claims stated below.

What is claimed is:

1. A solar generator capable of power tracking and electric characteristic curve measurement, which is connected to at least one external load, comprising
at least one solar panel receiving solar energy, converting said solar energy into electric energy, and outputting said electric energy;
an electric tracking-measuring circuit connected with said solar panel and said external load;
an illuminometer detecting an illumination on said solar panel; and
a processor connected with said illuminometer and said electric tracking-measuring circuit, controlling said electric tracking-measuring circuit to receive said electric energy and output said electric energy to said external load at a highest power, and controlling said electric tracking-measuring circuit to receive said electric energy and measuring a current-voltage characteristic curve of said electric energy to determine an operation status of said solar panel when said illumination is greater than a preset value.

2. The solar generator capable of power tracking and electric characteristic curve measurement according to claim 1, wherein before said processor controls said electric tracking-measuring circuit to receive said electric energy and output said electric energy to said external load at a highest power, said processor controls said electric tracking-measuring circuit to receive said electric energy and measure a reference current-voltage characteristic curve of said electric energy; said processor stores said reference current-voltage characteristic curve; then said processor compares a current-voltage characteristic curve measured afterward with said reference current-voltage characteristic curve to check an operation status of said solar panel.

3. The solar generator capable of power tracking and electric characteristic curve measurement according to claim 1, wherein before said processor controls said electric tracking-measuring circuit to receive said electric energy and output said electric energy to said external load at a highest power, a reference current-voltage characteristic curve is programmed in said processor beforehand; then said processor compares a current-voltage characteristic curve measured afterward with said reference current-voltage characteristic curve to check an operation status of said solar panel.

4. The solar generator capable of power tracking and electric characteristic curve measurement according to claim 1, wherein when said processor controls said electric tracking-measuring circuit to receive said electric energy, said processor controls said electric tracking-measuring circuit to incrementally increase or decrease voltage or current supplied by said solar panel to measure said current-voltage characteristic curve.

5. The solar generator capable of power tracking and electric characteristic curve measurement according to claim 2, wherein when said processor controls said electric tracking-measuring circuit to receive said electric energy, said processor controls said electric tracking-measuring circuit to incrementally increase or decrease voltage or current supplied by said solar panel to measure said reference current-voltage characteristic curve.

6. The solar generator capable of power tracking and electric characteristic curve measurement according to claim 1, wherein when said processor controls said electric tracking-measuring circuit to measure said current-voltage characteristic curve of said electric energy, said processor controls said electric tracking-measuring circuit to stop outputting said electric energy to said external load at a highest power.

7. The solar generator capable of power tracking and electric characteristic curve measurement according to claim 1, wherein during a process that said electric tracking-measuring circuit extracts a highest power from said electric energy and outputs said highest power to said external load, said processor periodically controls operations of said electric tracking-measuring circuit according to a relationship between said illumination and a preset illumination value.

8. The solar generator capable of power tracking and electric characteristic curve measurement according to claim 7, wherein when said illumination is higher than said preset illumination value, said processor controls said electric tracking-measuring circuit to measure said current-voltage characteristic curve of said electric energy.

9. The solar generator capable of power tracking and electric characteristic curve measurement according to claim 7, wherein when said illumination is lower than or equal to said preset illumination value, said processor controls said electric tracking-measuring circuit to keep on receiving said electric energy and outputting said electric energy to said external load at a highest power.

10. The solar generator capable of power tracking and electric characteristic curve measurement according to claim 1, wherein said electric tracking-measuring circuit and a DC (Direct Current)/DC converter are integrated into an electric tracking-measuring converter; said electric tracking-measuring converter is connected with said external load and said solar panel; said electric tracking-measuring converter receives said electric energy and outputs a stable DC power to said external load at a highest power.

11. The solar generator capable of power tracking and electric characteristic curve measurement according to claim 10, wherein said electric tracking-measuring converter is further connected to a DC/AC (Alternating Current) inverter; said electric tracking-measuring converter converts said electric energy into a stable DC power and outputs said stable DC power to said DC/AC inverter; said DC/AC inverter converts said stable DC power into a stable AC power and outputs said stable AC power to at least one external load connected to said DC/AC inverter.

12. The solar generator capable of power tracking and electric characteristic curve measurement according to claim 1, wherein said electric tracking-measuring circuit and a DC/AC inverter are integrated into an electric tracking-measuring inverter; said electric tracking-measuring inverter is connected with said external load and said solar panel; said electric tracking-measuring inverter receives said electric energy and outputs a stable AC power to said external load at a highest power.

13. The solar generator capable of power tracking and electric characteristic curve measurement according to claim 1, wherein said processor is a digital signal processor.

14. The solar generator capable of power tracking and electric characteristic curve measurement according to claim 1, wherein said electric tracking-measuring circuit is a voltage-decreasing type electric tracking-measuring circuit or a voltage-increasing type electric tracking-measuring circuit.

15. A method for realizing a solar generator capable of power tracking and electric characteristic curve measurement, which uses at least one solar panel to receive solar energy, convert said solar energy into electric energy and output said electric energy to an electric tracking-measuring circuit connected to at least one external load, comprising
step (A): controlling said electric tracking-measuring circuit to receive said electric energy and output said electric energy to said external load at a highest power; and
step (B): checking whether an illumination on said solar panel is greater than a preset illumination value;
if said illumination on said solar panel is greater than said preset illumination value, controlling said electric tracking-measuring circuit to measure a current-voltage characteristic curve of said electric energy to determine an operation status of said solar panel;
if said illumination on said solar panel is not greater than said preset illumination value, controlling said electric tracking-measuring circuit to return to said step (A).

16. The method for realizing a solar generator capable of power tracking and electric characteristic curve measurement according to claim 15, wherein before said step (A), a step of establishing a reference current-voltage characteristic curve is undertaken: controlling said electric tracking-measuring circuit to receive said electric energy and measure said reference current-voltage characteristic curve of said electric energy and then recording said reference current-voltage characteristic curve.

17. The method for realizing a solar generator capable of power tracking and electric characteristic curve measurement according to claim 16, wherein in said step (B), if said illumination on said solar panel is greater than said preset illumination value, said electric tracking-measuring circuit is controlled to receive said electric energy and measure said current-voltage characteristic curve of said electric energy; then said current-voltage characteristic curve is compared with said reference current-voltage characteristic curve to determine an operation status of said solar panel.

18. The method for realizing a solar generator capable of power tracking and electric characteristic curve measurement according to claim 15, wherein before said step (A), a reference current-voltage characteristic curve is programmed; in said step (B), if said illumination on said solar panel is greater than said preset illumination value, said electric tracking-measuring circuit is controlled to receive said electric energy and measure said current-voltage characteristic curve of said electric energy; then said current-voltage characteristic curve is compared with said reference current-voltage characteristic curve to determine an operation status of said solar panel.

19. The method for realizing a solar generator capable of power tracking and electric characteristic curve measurement according to claim 15, wherein in said step (B), when said electric tracking-measuring circuit receives said electric energy, said electric tracking-measuring circuit incrementally increases or decreases voltage or current supplied by said solar panel in measuring said current-voltage characteristic curve.

20. The method for realizing a solar generator capable of power tracking and electric characteristic curve measurement according to claim 16, wherein in said step of establishing said reference current-voltage characteristic curve, when said electric tracking-measuring circuit receives said electric energy, said electric tracking-measuring circuit incrementally increases or decreases voltage or current supplied by said solar panel in measuring said reference current-voltage characteristic curve.

21. The method for realizing a solar generator capable of power tracking and electric characteristic curve measurement according to claim 15, wherein after said step (A) has been undertaken for a given interval of time, said step (B) is undertaken.

22. The method for realizing a solar generator capable of power tracking and electric characteristic curve measurement according to claim 15, wherein in said step (B), when said electric tracking-measuring circuit is measuring said current-voltage characteristic curve of said electric energy, said electric tracking-measuring circuit is controlled to temporarily stop outputting said electric energy to said external load at a highest power.
